(19) United States
(12) Patent Application Publication
(10) Pub. No.: US 2015/0364599 A1
(43) Pub. Date: Dec. 17, 2015

(54) SEMICONDUCTOR DEVICE AND METHOD OF MANUFACTURING THE SAME

(71) Applicant: Kabushiki Kaisha Toshiba, Tokyo (JP)

(72) Inventor: Tetsuya Ohno, Nomi Ishikawa (JP)

(21) Appl. No.: 14/644,080

(22) Filed: Mar. 10, 2015

(30) Foreign Application Priority Data
Jun. 11, 2014 (JP) 2014-120594

(51) Int. Cl. H01L 29/78; H01L 29/20; H01L 29/66

(52) U.S. Cl. CPC H01L 29/7827; H01L 29/66446; H01L 29/2003

(57) ABSTRACT

In one embodiment, a semiconductor device includes a first semiconductor layer of a first conductivity type or an intrinsic type, and a second semiconductor layer of a second conductivity type provided on the first semiconductor layer. The device further includes a third semiconductor layer of the first conductivity type or an intrinsic type provided on the second semiconductor layer. The device further includes a control electrode and a first electrode provided on a side portion of the first, second or third semiconductor layer through at least one insulating layer, and a second electrode provided on the third semiconductor layer.

### CROSS REFERENCE TO RELATED APPLICATION

This application is based upon and claims the benefit of priority from the prior Japanese Patent Application No. 2014-120594, filed on Jun. 11, 2014, the entire contents of which are incorporated herein by reference.

### FIELD

Embodiments described herein relate to a semiconductor device and a method of manufacturing the same.

### BACKGROUND

A field effect transistor (FET) using a group III nitride semiconductor material, particularly a gallium nitride (GaN) based material, can bring out a large band gap, a high electric-field strength and the like with excellent material properties. The transistor is therefore attracting attention as a next generation power transistor such as a switching device and a power control device that need high power and high breakdown-voltage operation.

There are various structures of the power transistor. Each of the structures has an appropriate application that can make use of its features. For example, a vertical structure is demanded for the switching device that requires a low on-resistance, a high breakdown-voltage and a high current. Since the vertical structure is configured such that the breakdown voltage is applied in a vertical direction, it is desirable that differences between lattice constants and thermal expansion coefficients of a substrate and a semiconductor layer on the substrate are small. In a case where a group III nitride semiconductor crystal is epitaxially grown on a substrate, a bulk crystal (e.g., GaN self-supporting substrate or AlN self-supporting substrate) is often used as the substrate. However, there is a problem with these self-supporting substrates that they are hard to reduce the cost and to increase the diameter. In contrast, in a case where a GaN crystal is epitaxially grown on a different kind of substrate having a different lattice constant and a different thermal expansion coefficient (e.g., silicon substrate), a large number of dislocation defects are generated in the GaN crystal. Due to the existence of these dislocation defects, the breakdown voltage of the vertical structure in the vertical direction is lower than an expected physical property. It is therefore desired to enhance the crystallinity of the GaN and the device property of the power transistor.

### BRIEF DESCRIPTION OF THE DRAWINGS

FIGS. 1A to 1C are cross sectional views and a plan view showing a structure of a semiconductor device of a first embodiment;

FIGS. 2A to 11B are cross sectional views and plan views showing a method of manufacturing the semiconductor device of the first embodiment;

FIG. 12 is a cross sectional view showing a structure of a semiconductor device of a second embodiment;

FIGS. 13A to 19B are cross sectional views showing a method of manufacturing the semiconductor device of the second embodiment;

FIG. 20 is a cross sectional view showing a structure of a semiconductor device of a third embodiment; and

FIGS. 21A to 26B are cross sectional views showing a method of manufacturing the semiconductor device of the third embodiment.

### DETAILED DESCRIPTION

Embodiments will now be explained with reference to the accompanying drawings.

In one embodiment, a semiconductor device includes a first semiconductor layer of a first conductivity type or an intrinsic type, and a second semiconductor layer of a second conductivity type provided on the first semiconductor layer. The device further includes a third semiconductor layer of the first conductivity type or an intrinsic type provided on the second semiconductor layer. The device further includes a control electrode and a first electrode provided on a side portion of the first, second or third semiconductor layer through at least one insulating layer, and a second electrode provided on the third semiconductor layer.

### First Embodiment

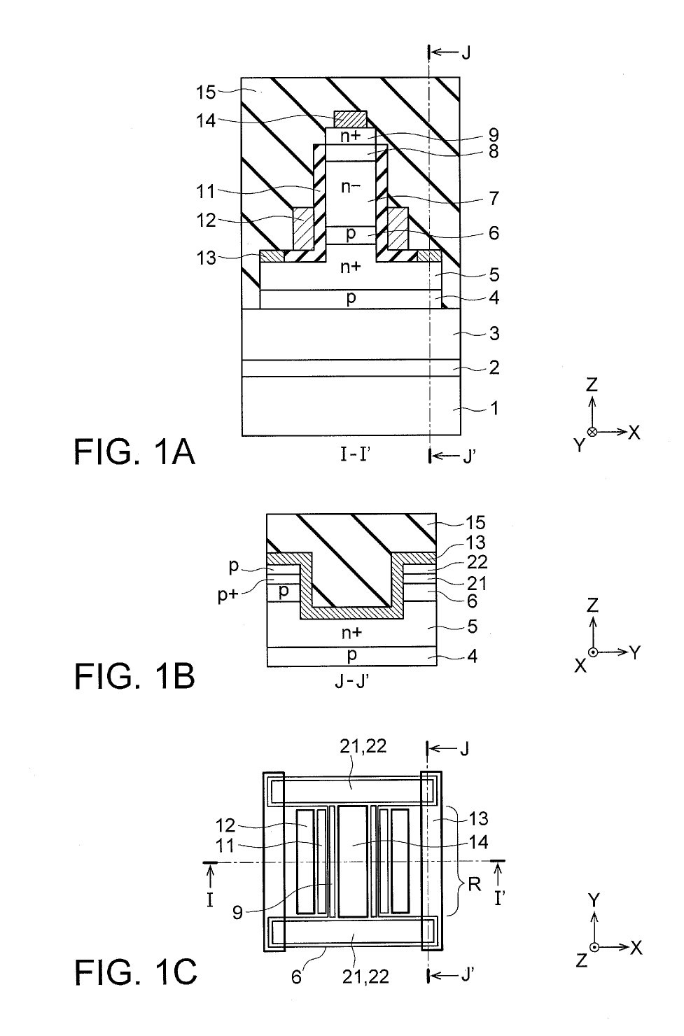

FIGS. 1A to 1C are cross sectional views and a plan view showing a structure of a semiconductor device of a first embodiment. The semiconductor device of the present embodiment includes a vertical transistor that makes use of a nitride semiconductor such as a GaN and an AlGaN.

FIG. 1A is a cross sectional view taken along a line I-I′ of the plan view of FIG. 1C. FIG. 1B is a cross sectional view taken along a line J-J′ of the plan view of FIG. 1C or the cross sectional view of FIG. 1A. Reference character R in FIG. 1C shows an operating region of the vertical transistor.

The semiconductor device of the present embodiment includes a substrate 1, a first buffer layer 2, a dislocation suppression layer 3, an electron block layer 4, a first n type contact layer 5 as an example of a first semiconductor layer, a first p type semiconductor layer 6 as an example of a second semiconductor layer, a first drift layer 7 as an example of a third semiconductor layer, a second buffer layer 8, and a second n type contact layer 9.

The semiconductor device of the present embodiment further includes gate insulators 11 as an example of at least one insulating layer, gate electrodes 12 as an example of a control electrode, source electrodes 13 as an example of a first electrode, a drain electrode 14 as an example of a second electrode, an interlayer dielectric 15 as another example of the at least one insulating layer, a p type contact layer 21, and a p type source layer 22.

Signs n, p, and i show semiconductor layers of an n type, p type, and i type (intrinsic type), respectively. The n type and the p type are examples of first and second conductivity types, respectively. The semiconductor layer of an i type means a semiconductor layer in which an n type impurity and a p type impurity are not intentionally contained. The semiconductor layer of i type is also called an undoped semiconductor layer.

In FIG. 1B and FIG. 1C, the illustrations of the substrate 1, the buffer layer 2, and the dislocation suppression layer 3 are omitted. An example of the substrate 1 is a semiconductor substrate such as a silicon substrate. FIGS. 1A to 1C show an X direction and a Y direction that are parallel to the substrate 1 and orthogonal to each other, and a Z direction that is orthogonal to the substrate 1. In the present specification, a +Z direction is treated as an upward direction, and a −Z direction is treated as a downward direction. For example, the positional relationship between the substrate 1 and the interlayer dielectric 15 is expressed that the substrate 1 is positioned below the interlayer dielectric 15.

The first buffer layer 2 is formed on the substrate 1. An example of the first buffer layer 2 is a laminated film that includes an AlN (aluminum nitride) layer, an AlGaN layer, a GaN layer, and the like.

The dislocation suppression layer 3 is formed on the first buffer layer 2. An example of the dislocation suppression layer is a laminated film that includes a plurality of nitride semiconductor layers, insulating layers, and the like. The dislocation suppression layer 3 is provided for restraining dislocations in the first buffer layer 2 from extending upward to reach an operating region R on the electron block layer 4. The thickness of the dislocation suppression layer 3 is, for example, about 4 μm to 10 μm.

The electron block layer 4 is formed on the dislocation suppression layer 3. An example of the electron block layer 4 is a p type GaN layer. The electron block layer 4 is provided for preventing leak current in the operating region R from flowing into the dislocation suppression layer 3. The thickness of the electron block layer 4 is, for example, about 1 μm to 3 μm.

The first n type contact layer 5 is formed on the electron block layer 4, and is in contact with the source electrode 13. The first n type contact layer 5 includes a lower region that has an area substantially equal to the electron block layer 4, and an upper region that has an area smaller than that of the lower region. An example of the first n type contact layer 5 is an n+ type GaN layer with an n type impurity doped at a relatively high concentration. An example of this n type impurity is a silicon (Si) atom. The first n type contact layer 5 is provided for reducing a contact resistance with the source electrode 13. The thickness of the first n type contact layer 5 is, for example, about 2 μm to 4 μm.

The first p type semiconductor layer 6 is formed on the first n type contact layer 5, and has an area substantially equal to that of the upper region of the first n type contact layer 5. An example of the first p type semiconductor layer 6 is a p type GaN layer with a p type impurity doped. An example of this p type impurity is a magnesium (Mg) atom. The thickness of the p type semiconductor layer 6 is, for example, about 0.02 μm to 1 μm.

The first drift layer 7 is formed on the first p type semiconductor layer 6, and has an area substantially equal to that of the first p type semiconductor layer 6. An example of the first drift layer 7 is an n− type GaN layer with an n type impurity doped at a concentration lower than that of the first n type contact layer 5, and may be an i type GaN layer. The thickness of the first drift layer 7 is, for example, about 4 μm to 10 μm.

The second buffer layer 8 is formed on the first drift layer 7, and has an area substantially equal to that of the first drift layer 7. The second buffer layer 8 is formed such that tunnel current is easy to flow, and an example of the second buffer layer 8 is a conductive laminated film that includes at least one of an AlN layer, a GaN layer, and an AlGaN layer. The semiconductor device of the present embodiment may not include the second buffer layer 8.

The second n type contact layer 9 is formed on the second buffer layer 8, and is in contact with the drain electrode 14. The second n type contact layer 9 has an area substantially equal to that of the second buffer layer 8. An example of the second n type contact layer 9 is an n+ type GaN layer. The second n type contact layer 9 is provided for reducing a contact resistance with the drain electrode 14.

The gate insulators 11 are formed on the upper portions of the lower region of the first n type contact layer 5, and on the side portions of the upper region of the first n type contact layer 5, the first p type semiconductor layer 6, the first drift layer 7, and the second buffer layer 8. An example of the gate insulators 11 is a silicon dioxide film. The thickness of the gate insulators 11 is, for example, about 10 nm to 50 nm.

The gate electrodes 12 are formed in a direction of the side portions of the upper region of the first n type contact layer 5, the first p type semiconductor layer 6, and the first drift layer 7, and is formed on the first n type contact layer 5, the first p type semiconductor layer 6, and the first drift layer 7 through the gate insulators 11. Specifically, the gate electrodes 12 are formed on the upper portions and the side portions of the first n type contact layer 5, the side portions of the first p type semiconductor layer 6, the side portions of the first drift layer 7 through the gate insulators 11. An example of the gate electrodes 12 is a metal layer. An example of this metal layer is a laminated film that includes at least one of a Pt (platinum) layer, a Ni (nickel) layer, and an Au (gold) layer. The gate electrodes 12 each have a shape extending in the Y direction.

The source electrodes 13 are formed in directions of the side portions of the upper region of the first n type contact layer 5. Specifically, the source electrodes 13 are formed on the side portions of the upper region of the first n type contact layer 5 through the gate insulators 11. Furthermore, the source electrodes 13 are formed on the lower region of the first n type contact layer 5, and are in contact with the upper portions of the lower region of the first n type contact layer 5. An example of the source electrodes 13 is an ohmic electrode, and is for example, a laminated film that includes at least one of an Al (aluminum) layer, a Ti (titanium) layer, a Ni layer, and an Au layer. The source electrodes 13 each have a shape extending in the Y direction.

The drain electrode 14 is formed on the first drift layer 7. Specifically, the drain electrode 14 is formed on the second n type contact layer 9, and is in contact with the upper portion of the second n type contact layer 9. An example of the drain electrode 14 is an ohmic electrode, and is for example, a laminated film that includes at least one of an Al layer, a Ti layer, a Ni layer, and an Au layer. The drain electrode 14 has a shape extending in the Y direction.

The interlayer dielectric 15 is formed such that the transistor on the dislocation suppression layer 3 is covered therewith. An example of the interlayer dielectric 15 is a silicon dioxide film.

The p type contact layers 21 are formed on the first p type semiconductor layer 6, and are in contact with the side portions of the source electrodes 13. An example of the p type contact layers 21 is a p+ type GaN layer with a p type impurity doped at a concentration higher than that of the first p type semiconductor layer 6. The p type contact layer 21 is a layer for reducing a potential difference between the source electrode 13 and the first p type semiconductor layer 6 through the p type source layer 22. The thickness of the p type contact layer 21 is, for example, about 0.01 μm to 2 μm.

The p type source layers 22 are formed on the p type contact layers 21, and are in contact with the side portions and the lower portions of the source electrodes 13. The p type source layers 22 each have an area substantially equal to that of the p type contact layer 21. The p type source layers 22 are provided for reducing a contact resistance with the source electrodes 13.

The semiconductor device of the present embodiment includes, as shown in FIG. 1A and FIG. 1C, two sets of the gate insulator 11, the gate electrode 12, and the source electrode 13. The gate insulator 11, the gate electrode 12, the source electrode 13 of one of the sets are disposed in a +X direction with respect to the first p type semiconductor layer 6 and the first drift layer 7, and the gate insulator 11, the gate electrode 12, and the source electrode 13 of the other set are disposed in a −X direction with respect to the first p type semiconductor layer 6 and the first drift layer 7. The first p type semiconductor layer 6 and the first drift layer 7 are disposed between the former set and the latter set.

As to the gate electrodes 12 and the source electrodes 13 of the present embodiment, the gate electrodes 12 are disposed inside the operating region R (beside the first p type semiconductor layer 6 and the first drift layer 7), and the source electrode 13 is disposed outside the operating region R (on the first n type contact layer 5).

In addition, the semiconductor device of the present embodiment includes, as shown in FIG. 1B and FIG. 1C, two sets of the p type contact layer 21 and the p type source layer 22. The p type contact layer 21 and the p type source layer 22 of one of the sets are disposed in a +Y direction with respect to the source electrodes 13, and the p type contact layer 21 and the p type source layer 22 of the other set are disposed in the −Y direction with respect to the source electrodes 13. The source electrodes 13 are disposed between the former set and the latter set.

As described above, the semiconductor device of the present embodiment includes the vertical transistor that makes use of nitride semiconductors. The nitride semiconductors of the present embodiment contain a large number of dislocation defects in regions close to the substrate 1, and contain fewer dislocation defects in regions farther from the substrate 1.

In the transistor of the present embodiment, since the drain electrode 14 is disposed on the first drift layer 7, the drain electrode 14 is disposed away from the regions containing a large number of dislocation defects. Therefore, according to the present embodiment, it is possible to suppress leak current due to dislocations, which consequently enables increasing the breakdown voltage of the transistor.

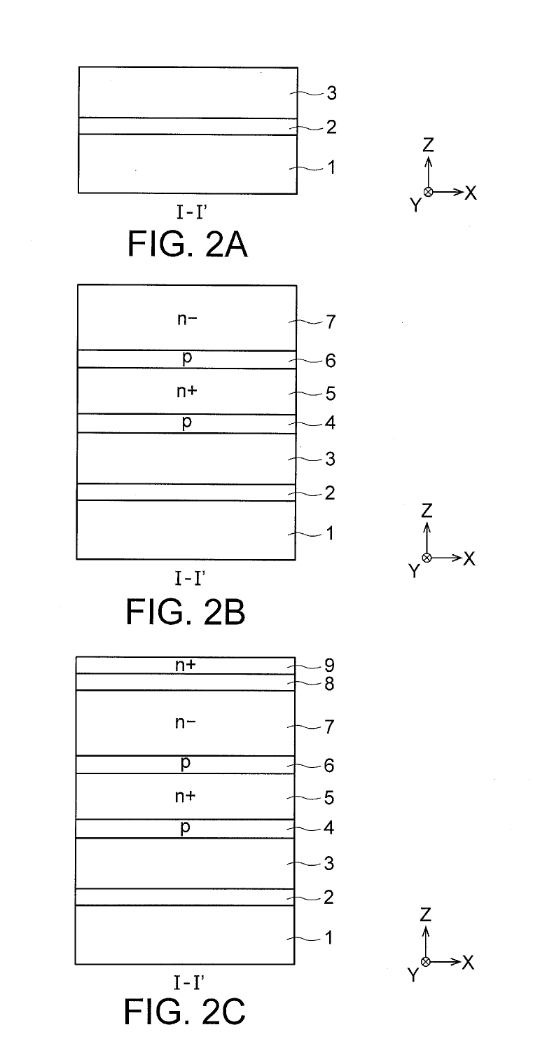

In addition, according to the present embodiment, by forming the electron block layer 4 on the dislocation suppression layer 3, it is possible to prevent leak current at the time of the operation from flowing into the dislocation suppression layer 3. FIGS. 2A to 11B are cross sectional views and plan views showing a method of manufacturing the semiconductor device of the first embodiment.

First, as shown in FIG. 2A, the first buffer layer 2 and the dislocation suppression layer 3 are formed one by one on the substrate 1. An example of the substrate 1 of the present embodiment is a silicon substrate, and may be a sapphire substrate.

Next, as shown in FIG. 2B, the electron block layer 4, the first n type contact layer 5, the first p type semiconductor layer 6, and the first drift layer 7 are formed one by one on the dislocation suppression layer 3.

Next, as shown in FIG. 2C, the second buffer layer 8 and the second n type contact layer 9 are formed one by one on the first drift layer 7.

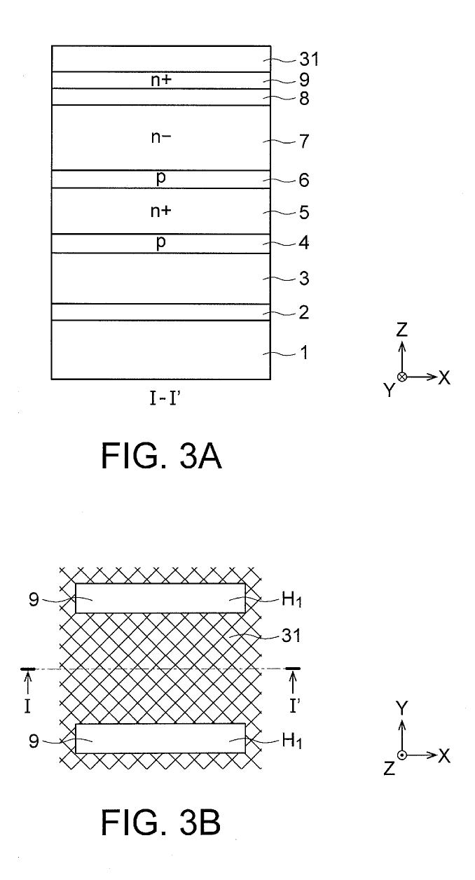

Next, as shown in FIG. 3A and FIG. 3B, in order to form openings H₁ extending in the X direction, a resist is applied on the second n type contact layer 9 to form a resist mask 31 with which an area other than the openings H₁ is covered, by means of lithography.

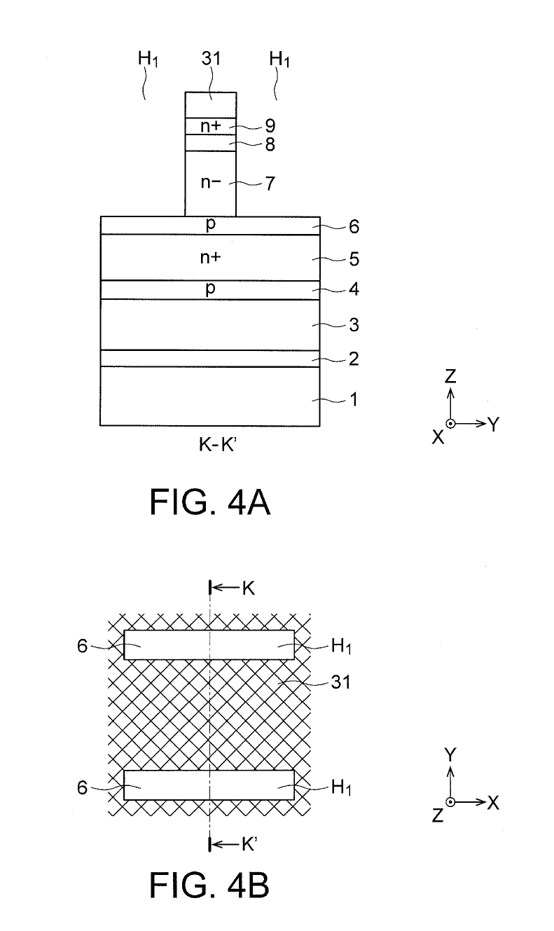

Next, as shown in FIG. 4A and FIG. 4B, by means of etching such as RIE (Reactive Ion Etching) using the resist mask 31, the openings H₁ that penetrate the second n type contact layer 9, the second buffer layer 8, and the first drift layer 7 to reach the first p type semiconductor layer 6 are formed. The side faces of the openings H₁ of the present embodiment are non-polar surfaces such as (1-100) plane (m-plane), and (11-20) plane (a-plane), and may be a semi-polar surface such as (11-22) plane. Next, the resist mask 31 is removed through a liftoff process.

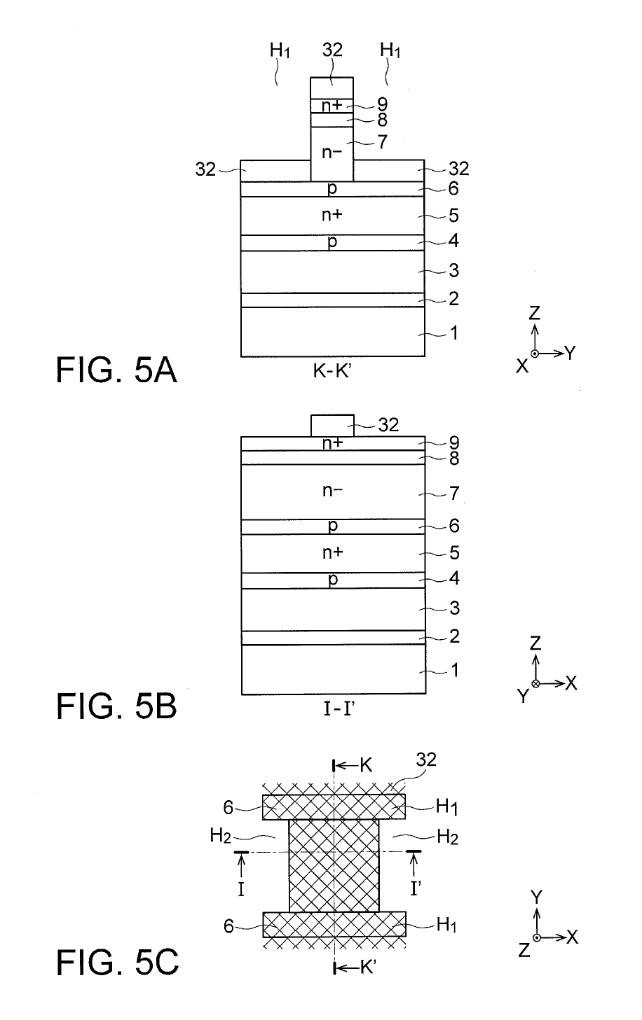

Next, as shown in FIGS. 5A to 5C, a resist mask 32 to form openings H₂ extending in the Y direction is formed by means of lithography. The side faces of the openings H₂ of the present embodiment are non-polar surfaces such as m-plane and a-plane, and may be a semi-polar surface.

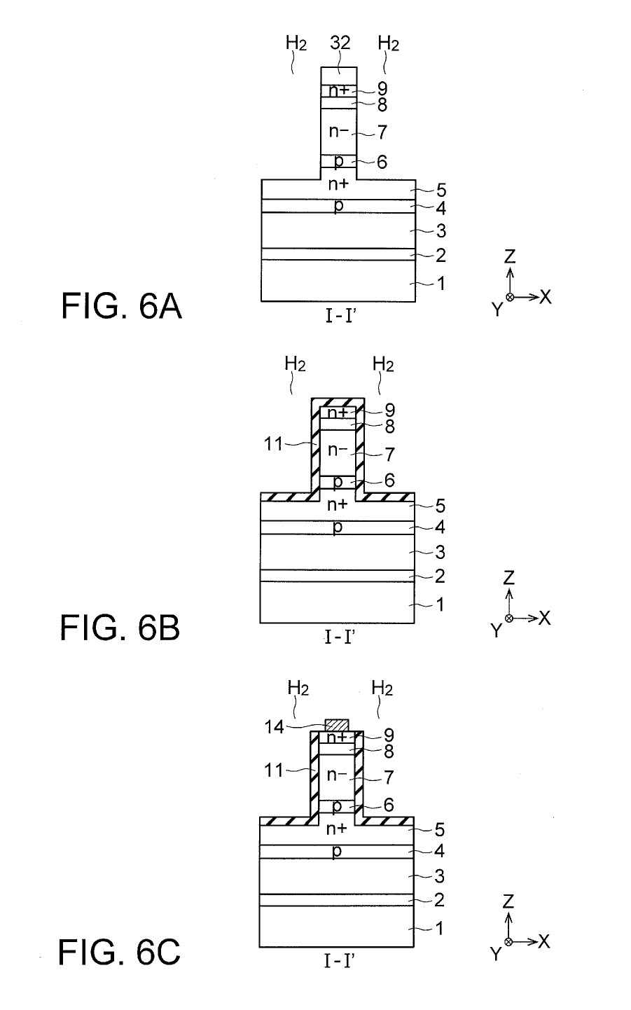

Next, as shown in FIG. 6A, by means of RIE, the openings H₂ that penetrate the second n type contact layer 9, the second buffer layer 8, the first drift layer 7, and the first p type semiconductor layer 6 to reach the first n type contact layer 5 are formed. Next, the resist mask 32 is removed.

Next, as shown in FIG. 6B, the gate insulator 11 is formed on the whole surface of the substrate 1. Consequently, the gate insulator 11 is formed on the first n type contact layer 5, the first p type semiconductor layer 6, the first drift layer 7, the second buffer layer 8, and the second n type contact layer 9.

Next, as shown in FIG. 6C, the gate insulator 11 on the second n type contact layer 9 is removed by means of lithography and etching. Next, the drain electrode 14 is formed on the second n type contact layer 9 in a state that an area other than a formation planned area of the drain electrode 14 is covered with a resist mask.

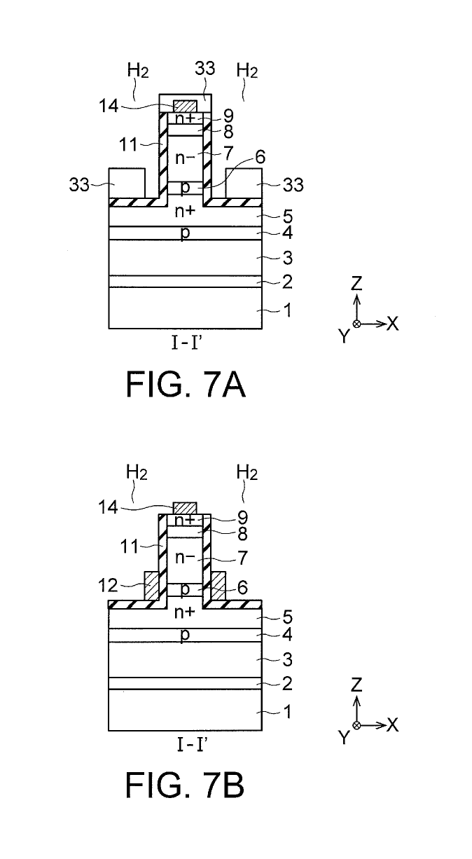

Next, as shown in FIG. 7A, resist masks 33 with which areas other than the formation planned area of the gate electrode 12 are covered are formed by means of lithography.

Next, as shown in FIG. 7B, the gate electrodes 12 are formed on the gate insulator 11 using the resist masks 33. Next, the resist masks 33 are removed.

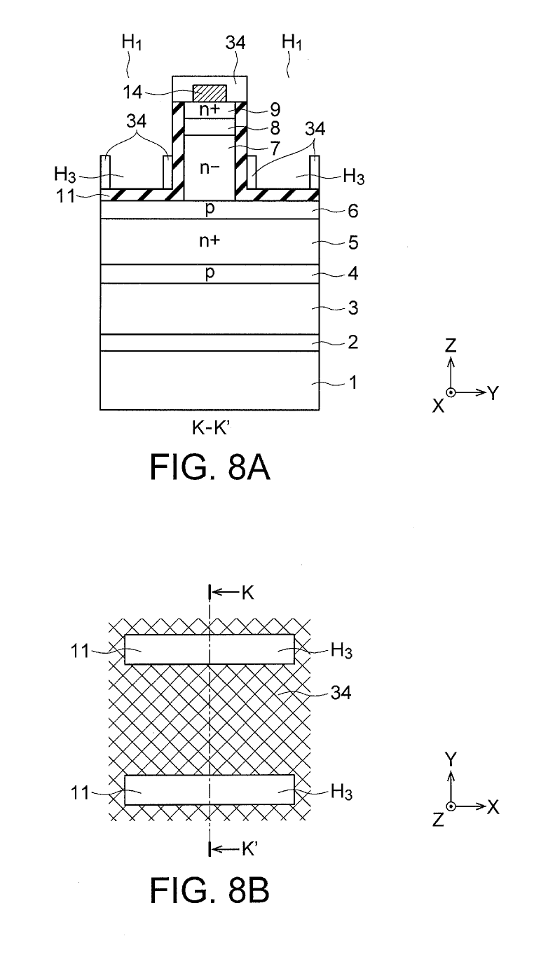

Next, as shown in FIG. 8A and FIG. 8B, a resist mask 34 that has openings H₃ extending in the X direction is formed by means of lithography. The openings H₃ are formed in formation planned areas of the p type contact layers 21 and the p type source layers 22.

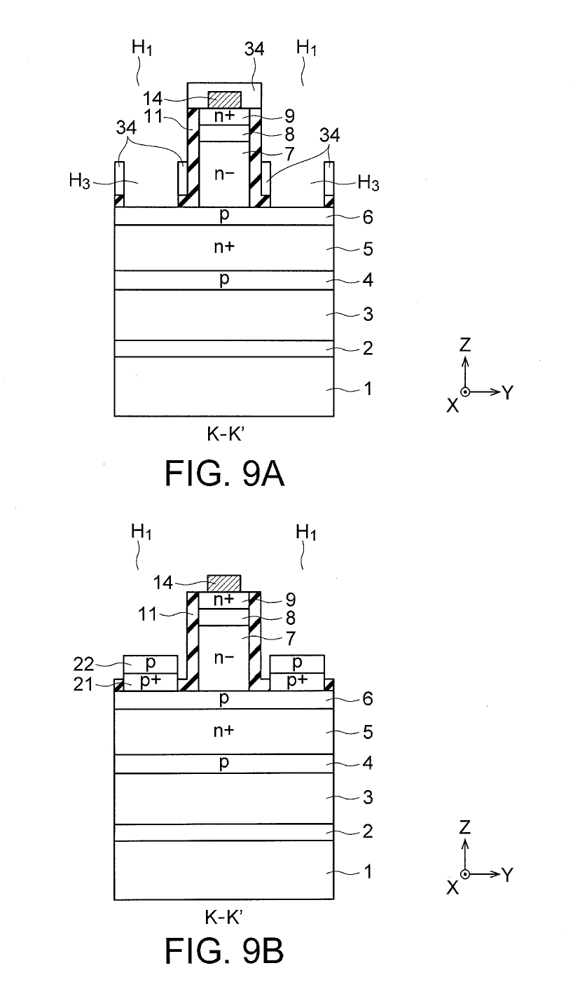

Next, as shown in FIG. 9A and FIG. 9B, the gate insulators 11 in the openings H₃ are removed by means of etching or the like. Consequently, the first p type semiconductor layer 6 is exposed in the openings H₃. Next, the p type contact layers 21 and the p type source layers 22 are formed one by one on the exposed first p type semiconductor layer 6. Next, the resist masks 34 are removed.

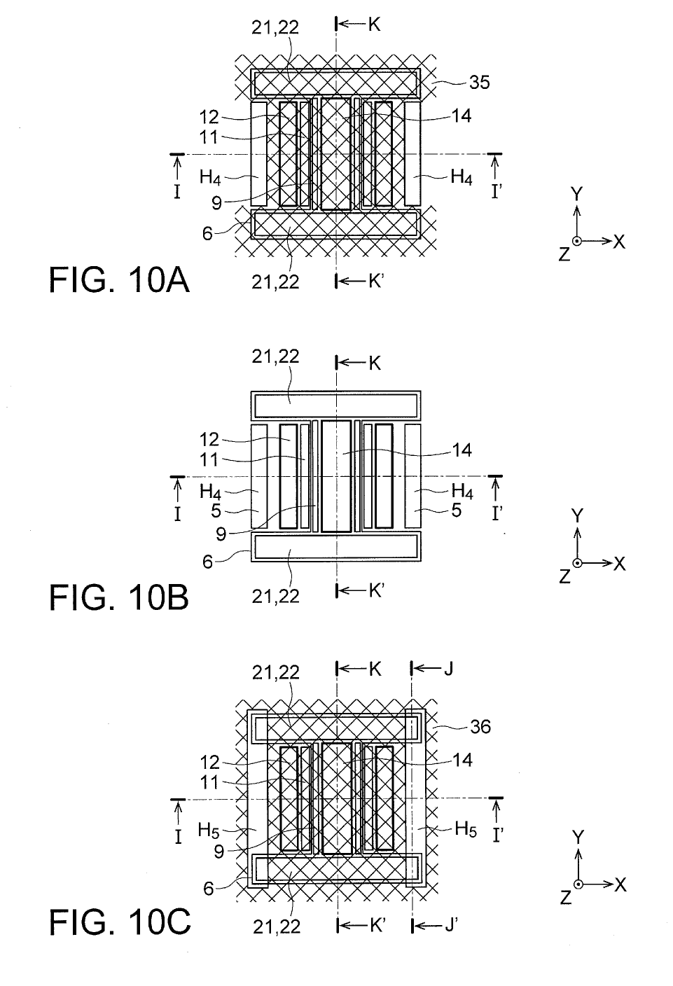

Next, as shown in FIG. 10A, a resist mask 35 that has openings H₄ used to remove the gate insulators 11 in formation planned areas of the source electrodes 13 is formed.

Next, as shown in FIG. 10B, the gate insulators 11 in the openings H₄ are removed by means of RIE. Consequently, the first n type contact layer 5 is exposed in the openings H₄. Next, the resist mask 35 is removed.

Next, as shown in FIG. 10C, a resist mask 36 that has openings H₅ is formed in the formation planned areas of the source electrodes 13.

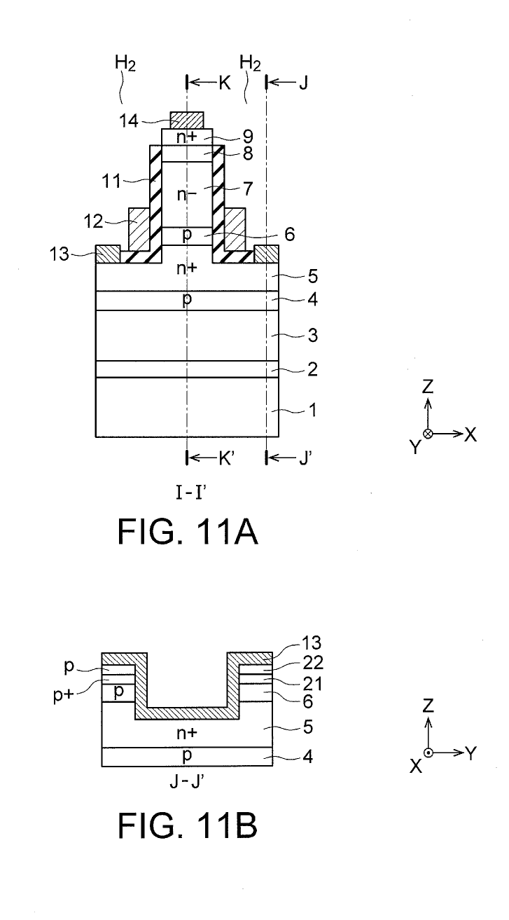

Next, as shown in FIG. 11A and FIG. 11B, the source electrodes 13 are formed on the upper portion and the side portions of the first n type contact layer 5, the side portions of the first p type semiconductor layer 6, the side portions of the p type contact layers 21, and the side portions and the upper portions of the p type source layers 22, in the openings H₅. Next, the resist mask 36 is removed. In such a manner, the transistor is formed on the substrate 1.

Subsequently, the interlayer dielectric 15 is formed on the substrate 1. Furthermore, various interlayer dielectrics, interconnect layers, and the like are formed on the substrate 1. In such a manner, the semiconductor device of the first embodiment can be manufactured.

As described above, the semiconductor device of the present embodiment includes the gate electrodes 12 and the source electrodes 13 in the directions of the side portions of the first n type contact layer 5, the first p type semiconductor layer 6, or the first drift layer 7, and includes the drain electrode 14 on the first drift layer 7. Therefore, according to the present embodiment, it is possible to isolate the transistor from the regions containing a large number of dislocation defects, and to restrain current collapse by passing electrons through the first drift layer 7, which consequently enables increasing the breakdown voltage of the transistor.

### Second Embodiment

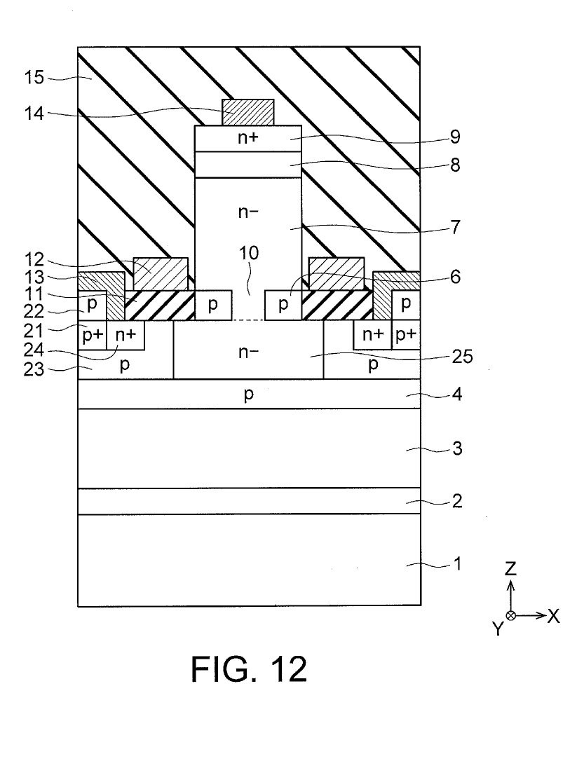

FIG. 12 is a cross sectional view showing a structure of a semiconductor device of a second embodiment.

The semiconductor device of the present embodiment includes, in addition to the components of the semiconductor device of the first embodiment, second p type semiconductor layers 23 and third n type contact layers 24. In addition, in the present embodiment, the first n type contact layer 5 of the first embodiment is replaced with a second drift layer 25. The second p type semiconductor layers 23 are an example of a fifth semiconductor layer. The third n type contact layers 24 are an example of a fourth semiconductor layer. The second drift layer 25 is an example of a first semiconductor layer.

The second p type semiconductor layers 23 are formed on the electron block layer 4, and are in contact with the side portions of the second drift layer 25. An example of the second p type semiconductor layers 23 is a p type GaN layer. The second p type semiconductor layers 23 are in contact with the lower portions and side portions of the third n type contact layers 24, and are formed between the second drift layer 25 and the third n type contact layers 24. The second p type semiconductor layers 23 below the gate electrodes 12 are sandwiched between the second drift layer 25 and the third n type contact layers 24, and function as channels of the vertical transistor.

The third n type contact layers 24 are formed on the second p type semiconductor layers 23 together with the p type contact layers 21. The third n type contact layers 24 are in contact with the lower portions of the source electrodes 13, and are electrically connected to the source electrodes 13. An example of the third n type contact layers 24 is an n+ type GaN layer.

The gate insulators 11 of the present embodiment are formed on the second drift layer 25, the second p type semiconductor layers 23, and the third n type contact layers 24. In addition, the gate electrodes 12 of the present embodiment are formed on the second drift layer 25, the second p type semiconductor layers 23, and the third n type contact layer 24 via the gate insulators 11, and are formed on the side portions of the first drift layer 7 via the interlayer dielectric 15. In addition, the source electrodes 13 of the present embodiment are formed on the third n type contact layers 24, and are formed on the side portions of the first p type semiconductor layer 6 and the first drift layer 7 via the gate insulators 11 and the interlayer dielectric 15.

The first p type semiconductor layer 6 of the present embodiment includes an opening 10 extending in the Y direction in the central portion of the first p type semiconductor layer 6. Consequently, the first drift layer 7 is in contact with the first p type semiconductor layer 6, and is in contact with the second drift layer 25 through the opening 10. The second drift layer 25 of the present embodiment is an n− type GaN layer.

The semiconductor device of the present embodiment includes two sets of the gate insulator 11, the gate electrode 12, the source electrode 13, the p type contact layer 21, the p type source layer 22, the second p type semiconductor layer 23, and the third n type contact layer 24. One of the sets is disposed in the +X direction with respect to the second drift layer 25, the first p type semiconductor layer 6, and the first drift layer 7, and the other set is disposed in the −X direction with respect to the second drift layer 25, the first p type semiconductor layer 6, and the first drift layer 7. The second drift layer 25, the first p type semiconductor layer 6, and the first drift layer 7 are disposed between the former set and the latter set.

The p type contact layers 21 and the p type source layers 22 of the present embodiment may be disposed, as with the first embodiment, in the ±Y directions with respect to the second drift layer 25, the first p type semiconductor layer 6, and the first drift layer 7.

When the transistor of the present embodiment is turned on, upper layers of the second p type semiconductor layers 23 below the gate electrodes 12 are channelized to be brought into a conduction state, and electrons flow from the third n type contact layers 24 to the second drift layer 25 via the second p type semiconductor layers 23. These electrons flow into the first drift layer 7 through the opening 10.

According to the present embodiment, by forming the opening 10 in the vicinity of the central portion of the first p type semiconductor layer 6, electrons flow in the crystals of the first drift layer 7 through the opening 10. Therefore, according to the present embodiment, electrons flowing through the crystals of the first drift layer 7 can restrain current collapse, which consequently enables increasing the breakdown voltage of the transistor.

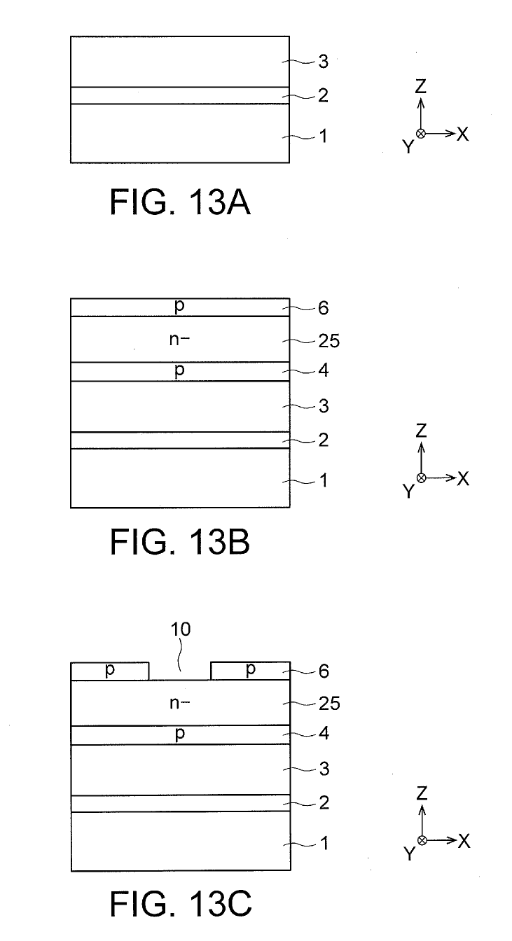

FIGS. 13A to 19B are cross sectional views showing a method of manufacturing the semiconductor device of the second embodiment.

First, as shown in FIG. 13A, the first buffer layer 2 and the dislocation suppression layer 3 are formed one by one on the substrate 1.

Next, as shown in FIG. 13B, the electron block layer 4, the second drift layer 25, and the first p type semiconductor layer 6 are formed one by one on the dislocation suppression layer 3.

Next, as shown in FIG. 13C, the opening 10 is formed in the first p type semiconductor layer 6 by means of lithography and RIE. The side faces of the opening 10 of the present embodiment are non-polar surfaces such as m-plane and a-plane.

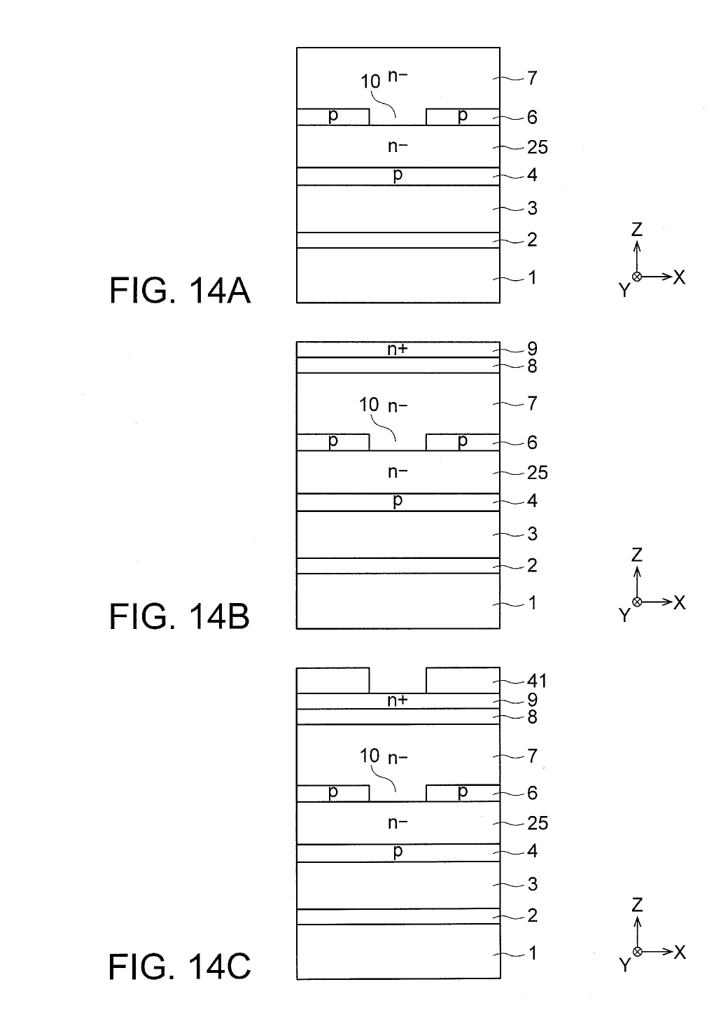

Next, as shown in FIG. 14A, the first drift layer 7 is formed on the first p type semiconductor layer 6 including the opening 10. Consequently, the first drift layer 7 is embedded in the opening 10, which brings the first p type semiconductor layer 6 and the first drift layer 7 into contact with the second drift layer 25.

Next, as shown in FIG. 14B, the second buffer layer 8 and the second n type contact layer 9 are formed one by one on the first drift layer 7.

Next, as shown in FIG. 14C, resist masks 41 with which areas other than a formation planned area of the drain electrode 14 are covered are formed by means of lithography.

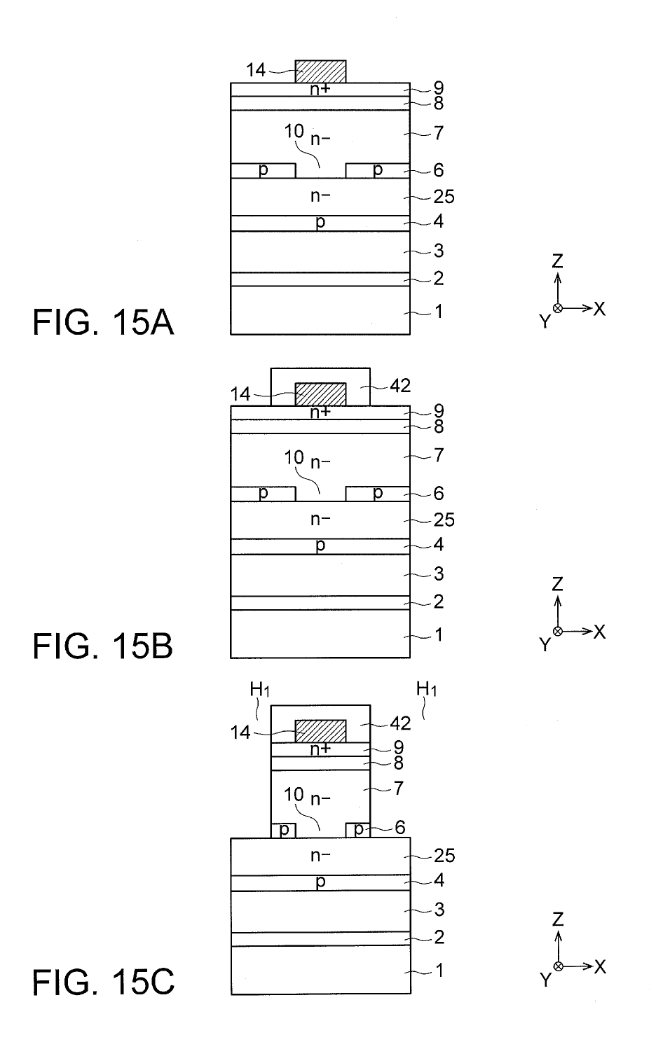

Next, as shown in FIG. 15A, the drain electrode 14 is formed on the second n type contact layer 9 using the resist masks 41. Next, the resist masks 41 are removed.

Next, as shown in FIG. 15B, a resist mask 42 used to form openings H₁ extending in the Y direction is formed by means of lithography.

Next, as shown in FIG. 15C, the openings H₁ that penetrate the second n type contact layer 9, the second buffer layer 8, the first drift layer 7, and the first p type semiconductor layer 6 to reach the second drift layer 25 are formed by means of RIE. Next, the resist mask 42 is removed.

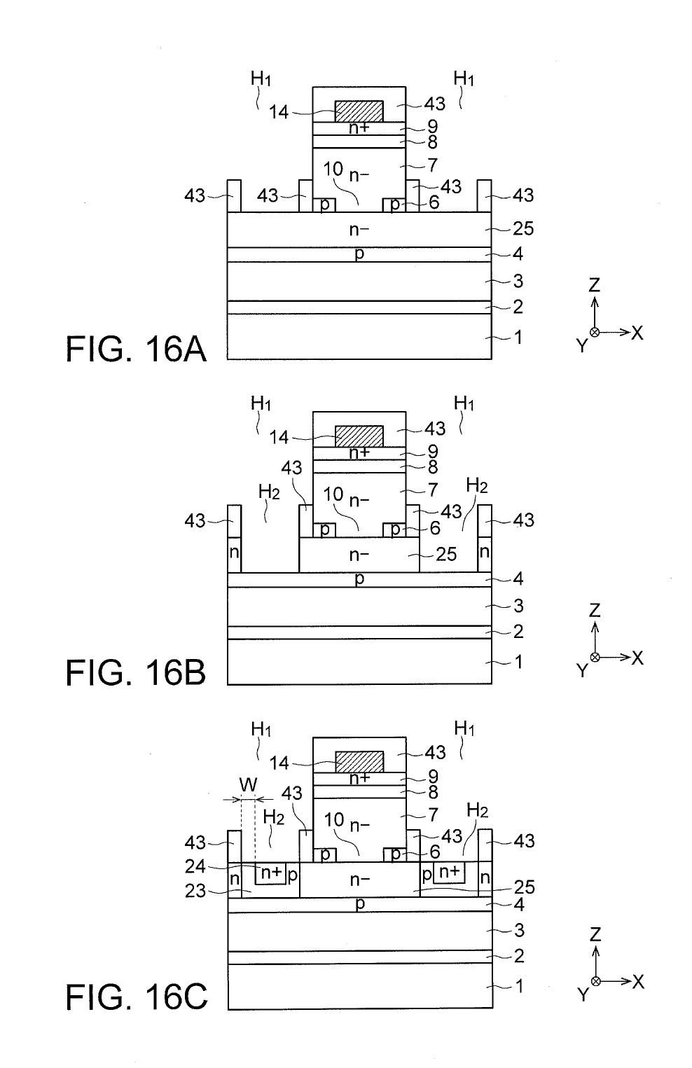

Next, as shown in FIG. 16A, resist masks 43 including openings H₂ extending in the Y direction are formed by means of lithography. The openings H₂ are formed in formation planned areas of the second p type semiconductor layers 23 and the third n type contact layers 24.

Next, as shown in FIG. 16B, the second drift layer 25 in the openings H₂ is removed by means of RIE. Consequently, the electron block layer 4 is exposed in the openings H₂.

Next, as shown in FIG. 16C, the second p type semiconductor layers 23 are formed the upper portions of the electron block layer 4 in the openings H₂ and on the side portions of the second drift layer 25. Next, the third n type contact layers 24 are formed on the second p type semiconductor layers 23 in the openings H₂. Next, the resist masks 43 are removed. Reference character W denotes the width of the most upper portions of the second p type semiconductor layers 23 in the X direction. The width W may be any value as long as the second p type semiconductor layers 23 can be conductive by pinch-off and channelizing, and for example, is adjusted to about 0.02 μm to 1 μm. In addition, the third n type contact layers 24 may be formed by ion implantation of n type impurities to the second p type semiconductor layers 23. The thickness of the second p type semiconductor layers 23 is set in conformity with the thickness of the second drift layer 25. In addition, the thickness of the third n type contact layers 24 is adjusted to, for example, about 1 μm to 2 μm, taking diffusion of an Mg from the second p type semiconductor layers 23 into account.

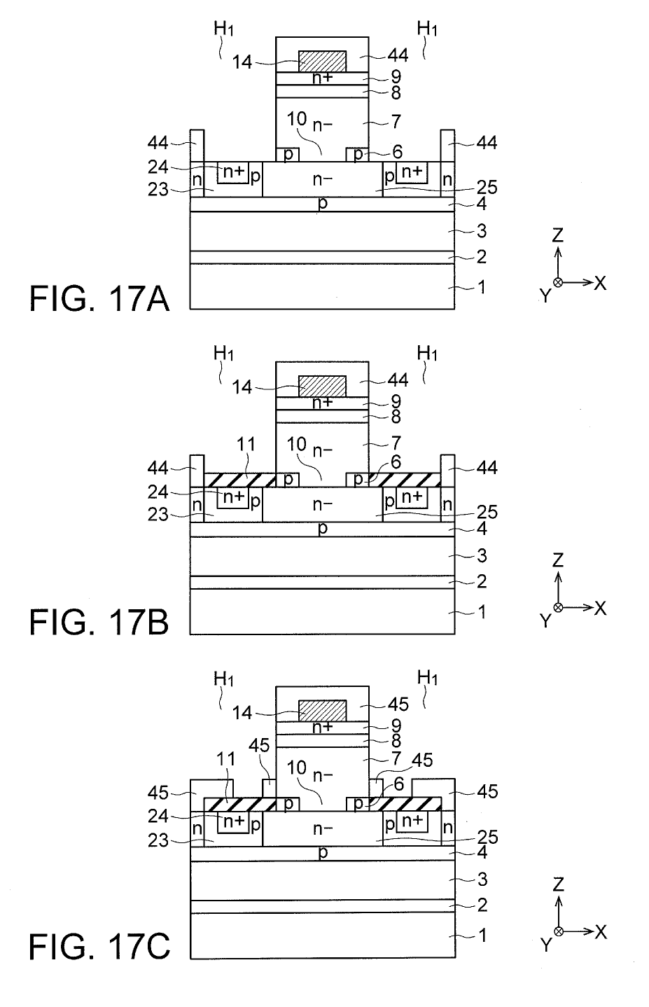

Next, as shown FIG. 17A, resist masks 44 with which areas other than formation planned areas of the gate insulators 11 are covered are formed by means of lithography.

Next, as shown in FIG. 17B, using the resist masks 44, the gate insulators 11 are formed on the second drift layer 25, the second p type semiconductor layers 23, and the third n type contact layers 24. Next, the resist masks 44 are removed.

Next, as shown in FIG. 17C, resist masks 45 with which areas other than formation planned areas of the gate electrodes 12 are covered are formed by means of lithography.

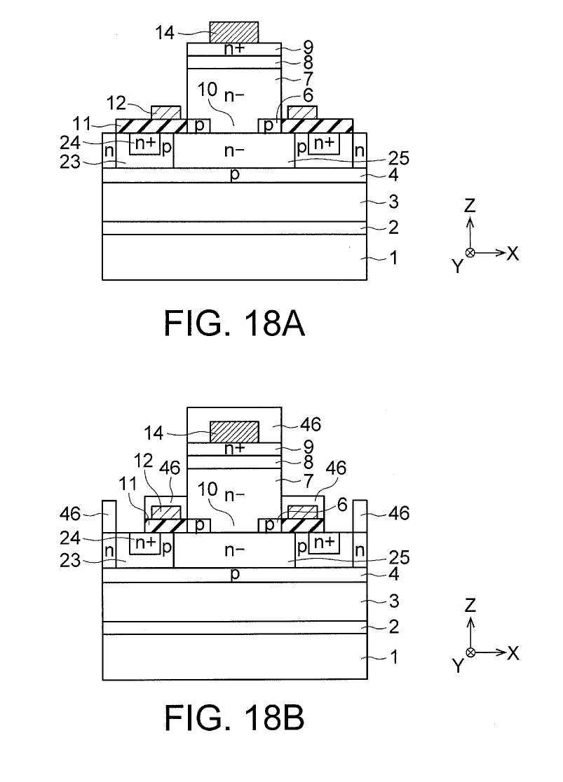

Next, as shown in FIG. 18A, using the resist masks 45, the gate electrodes 12 are formed on the second drift layer 25, the second p type semiconductor layers 23, and the third n type contact layers 24 via the gate insulators 11. Next, the resist masks 45 are removed.

Next, as shown in FIG. 18B, by means of lithography, resist masks 46 with which areas other than formation planned areas of the source electrodes 13, the p type contact layers 21, and the p type source layers 22 are covered are formed. Next, by means of etching or the like, the gate insulators 11 in the formation planned areas of the source electrodes 13, the p type contact layers 21, and the p type source layers 22 are removed to expose the second p type semiconductor layers 23 and the third n type contact layers 24 from the gate insulators 11.

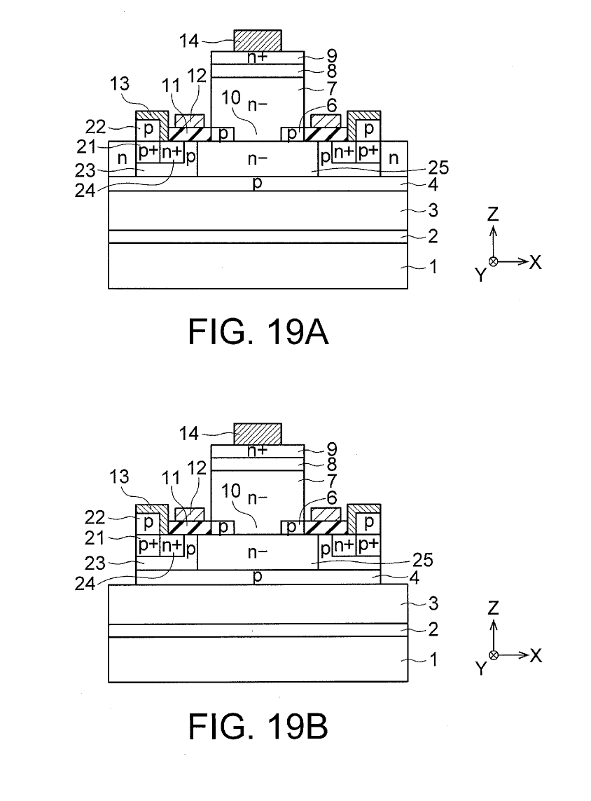

Next, as shown in FIG. 19A, by means of RIE, the second p type semiconductor layers 23 and the third n type contact layers 24 in the formation planned areas of the source electrodes 13, the p type contact layers 21, and the p type source layers 22 are removed. Next, the p type contact layers 21 and the p type source layers 22 are formed one by one on the second p type semiconductor layer 23. Next, the source electrodes 13 are formed on the third n type contact layers 24 and the p type source layers 22. Next, the resist masks 46 are removed.

Next, as shown in FIG. 19B, trenches for the element isolation are formed on the substrate 1. Consequently, the transistor is formed on the substrate 1.

Subsequently, the interlayer dielectric 15 is formed on the substrate 1. Furthermore, various interlayer dielectrics, interconnect layers, and the like are formed on the substrate 1.

In such a manner, the semiconductor device of the second embodiment can be manufactured.

As described above, the semiconductor device of the present embodiment includes the gate electrodes 12 and the source electrode 13 in the directions of the side portions of the second drift layer 25, the first p type semiconductor layer 6, or the first drift layer 7, and includes the drain electrode 14 on the first drift layer 7. Therefore, according to the present embodiment, as with the first embodiment, it is possible to isolate the transistor from the regions containing a large number of dislocation defects, and to restrain current collapse by passing electrons through the crystals of the first drift layer 7, which consequently enables increasing the breakdown voltage of the transistor.

### Third Embodiment

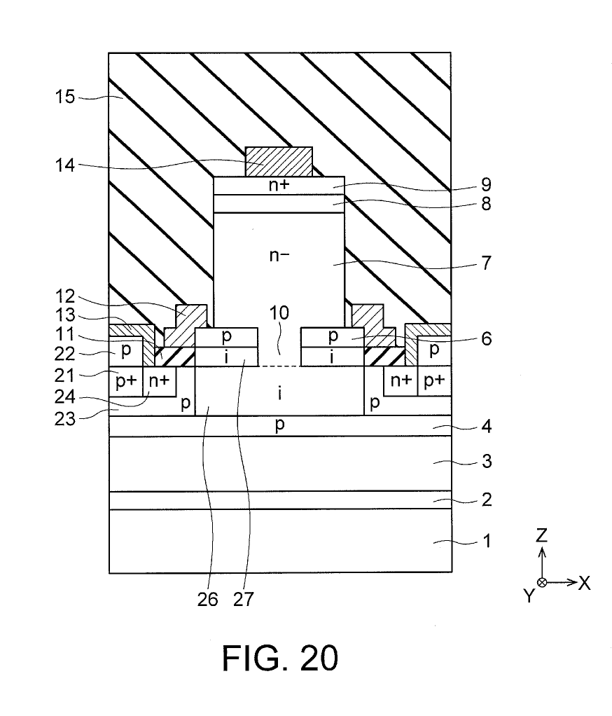

FIG. 20 is a cross sectional view showing a structure of a semiconductor device of a third embodiment.

The semiconductor device of the present embodiment includes, instead of the second drift layer 25 of the second embodiment, an electron transport layer 26 and an electron supply layer 27. The electron transport layer 26 is an example of a first nitride semiconductor layer of the first semiconductor layer. The electron supply layer 27 is an example of a second nitride semiconductor layer of the first semiconductor layer.

The electron transport layer 26 is formed on the electron block layer 4. An example of the electron transport layer 26 is an i type GaN layer.

The electron supply layer 27 is formed on the electron transport layer 26. An example of the electron supply layer 27 is an i type AlGaN layer.

The first p type semiconductor layer 6 and the electron supply layer 27 of the present embodiment have the opening 10 extending in the Y direction, in the central portions thereof. Consequently, the first drift layer 7 is in contact with electron transport layer 26 through the opening 10. The first p type semiconductor layer 6 of the present embodiment is a p type AlGaN layer and may be a p type GaN layer.

The gate insulators 11 of the present embodiment are formed on the second p type semiconductor layers 23 and the third n type contact layers 24. In addition, the gate electrodes 12 of the present embodiment are formed on the second p type semiconductor layers 23 and the third n type contact layers 24 via the gate insulators 11, are electrically connected to the first p type semiconductor layer 6, and are formed on the side portions of the first drift layer 7 via the interlayer dielectric 15. In addition, the source electrodes 13 of the present embodiment are formed on the third n type contact layers 24, and are formed on the side portions of the electron supply layer 27, the first p type semiconductor layer 6 and the first drift layer 7 via the gate insulators 11 and the interlayer dielectric 15.

The first p type semiconductor layer 6 of the present embodiment has a function of raising the potential of two-dimensional electron gas (2DEG) in a channel of a heterointerface between the electron transport layer 26 and the electron supply layer 27. Therefore, when the transistor of the present embodiment is in an off state, an energy level of a conduction band in the heterointerface becomes higher than the Fermi level thereof, and a 2DEG layer of the channel is brought into a depleted state.

On the other hand, when the transistor of the present embodiment is turned on, the second p type semiconductor layers 23 below the gate electrodes 12 are channelized and brought into a conduction state, and electrons flow from the third n type contact layers 24 to the electron transport layer 26 via the second p type semiconductor layers 23. At the same time, positive holes are led from the first p type semiconductor layer 6 to the heterointerface, which generates electrons in the heterointerface. Consequently, electrons flow to the first drift layer 7 through the opening 10.

According to the present embodiment, it is possible to enhance the pinch-off of the transistor, and to improve the channel mobility.

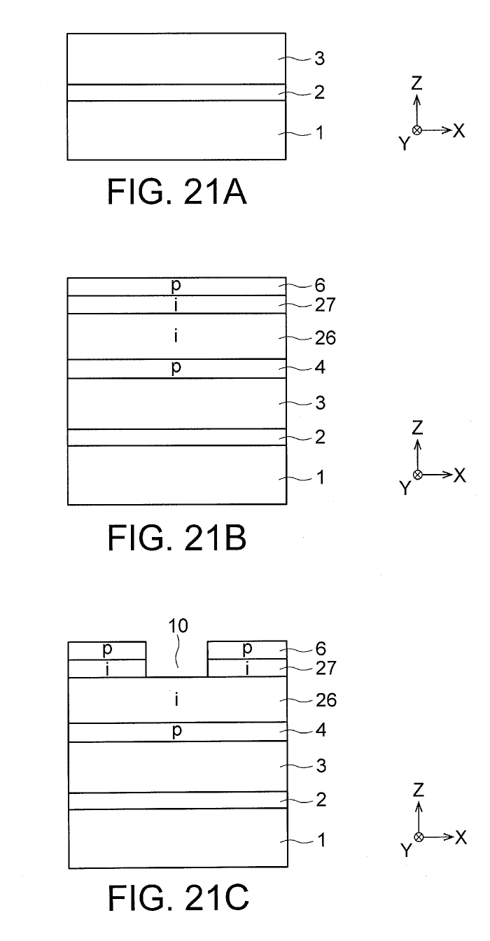

FIGS. 21A to 26B are cross sectional views showing a method of manufacturing the semiconductor device of the third embodiment.

First, as shown in FIG. 21A, the first buffer layer 2 and the dislocation suppression layer 3 are formed one by one on the substrate 1.

Next, as shown in FIG. 21B, the electron block layer 4, the electron transport layer 26, the electron supply layer 27, and the first p type semiconductor layer 6 are formed one by one on the dislocation suppression layer 3. The thickness of the electron transport layer 26 is, for example, 2 to 4 μm. In addition, the thickness of the electron supply layer 27 is, for example, 25 nm.

Next, as shown in FIG. 21C, by means of lithography and RIE, the opening 10 is formed in the first p type semiconductor layer 6 and the electron supply layer 27. The side faces of the first p type semiconductor layer 6 and the electron supply layer 27 of the present embodiment are non-polar surfaces such as m-plane and a-plane, and may be semi-polar surfaces.

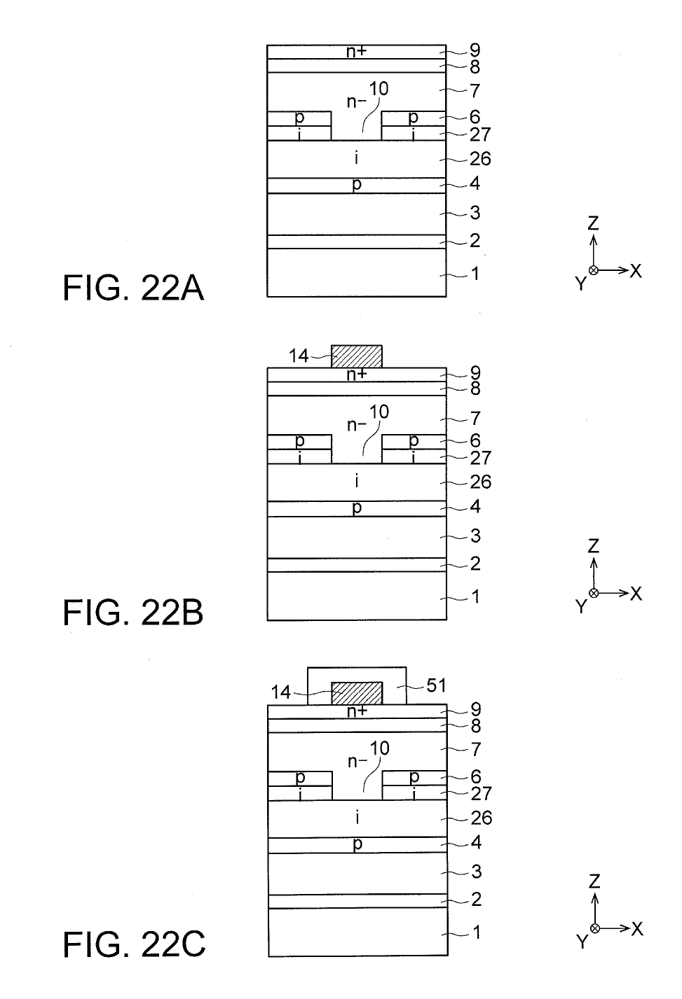

Next, as shown in FIG. 22A, the first drift layer 7 is formed on the first p type semiconductor layer 6 and the electron supply layer 27 that have the opening 10. Consequently, the first drift layer 7 is embedded in the opening 10, and the first drift layer 7 is in contact with the electron transport layer 26. Next, the second buffer layer 8 and the second n type contact layer 9 are formed one by one on the first drift layer 7.

Next, as shown in FIG. 22B, as with the second embodiment, the drain electrode 14 is formed on the second n type contact layer 9.

Next, as shown in FIG. 22C, a resist mask 51 used to form openings H₁ extending in the Y direction is formed by means of lithography.

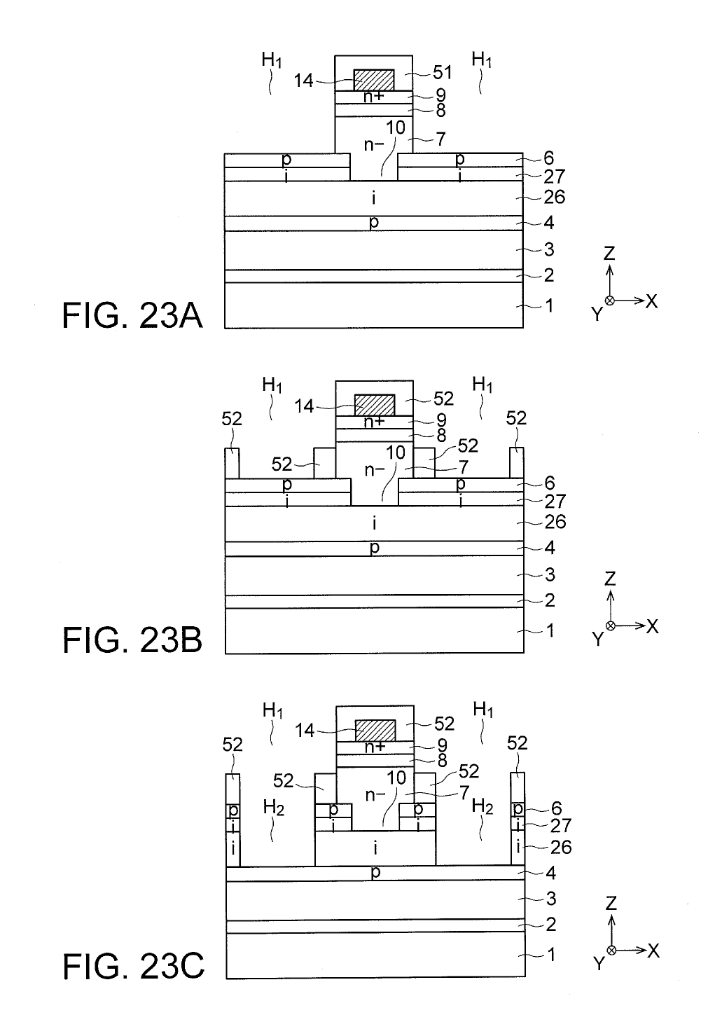

Next, as shown in FIG. 23A, by means of RIE or the like, the openings H₁ that penetrate the second n type contact layer 9, the second buffer layer 8, and the first drift layer 7 to reach the first p type semiconductor layer 6 are formed. Next, the resist mask 51 is removed.

Next, as shown in FIG. 23B, resist masks 52 used to form openings H₂ extending in the Y direction are formed by means of lithography. The openings H₂ are formed in formation planned areas of the second p type semiconductor layer 23 and the third n type contact layers 24.

Next, as shown in FIG. 23C, by means of RIE, the openings H₂ that penetrate the first p type semiconductor layer 6, the electron supply layer 27, and the electron transport layer 26 to reach the electron block layer 4 are formed.

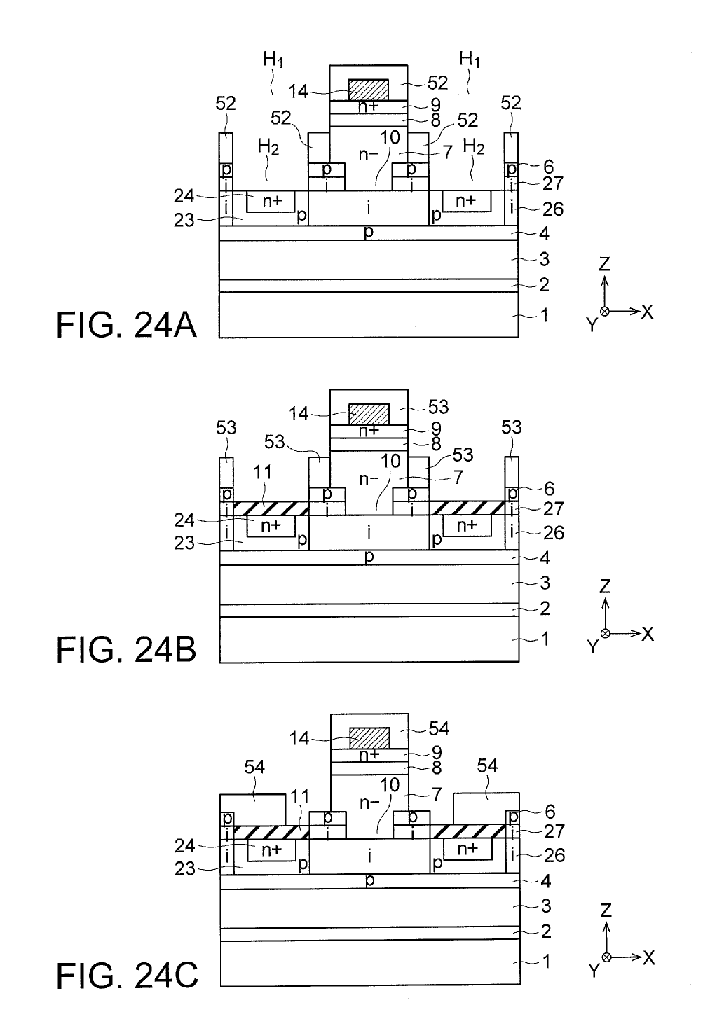

Next, as shown in FIG. 24A, using the resist masks 52, the second p type semiconductor layers 23 are formed on the upper portions of the electron block layer 4 in the openings H₂ and on the side portions of the electron transport layer 26.

Next, the third n type contact layers 24 are formed on the second p type semiconductor layers 23 in the openings H₂. Next, the resist masks 52 are removed. The third n type contact layers 24 may be formed by ion implantation of n type impurities to the second p type semiconductor layers 23.

Next, as shown in FIG. 24B, using resist masks 53, the gate insulators 11 are formed on the second p type semiconductor layers 23 and the third n type contact layers 24. Next, the resist masks 53 are removed. The thickness of the gate insulators 11 of the present embodiment is set in conformity with the thickness of the electron supply layer 27.

Next, as shown in FIG. 24C, by means of lithography, resist masks 54 with which areas other than formation planned areas of the gate electrodes 12 are covered are formed.

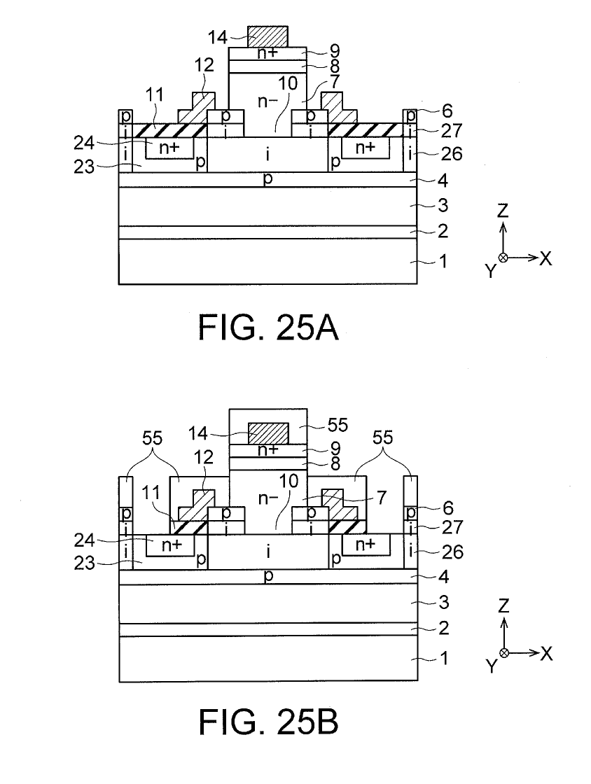

Next, as shown in FIG. 25A, using the resist masks 54, the gate electrodes 12 are formed on the second p type semiconductor layers 23 and the third n type contact layers 24 via the gate insulators 11. At this point, the gate electrodes 12 are also formed on the first p type semiconductor layer 6, and are electrically connected to the first p type semiconductor layer 6. Next, the resist masks 54 are removed.

Next, as shown in FIG. 25B, by means of lithography, resist masks 55 with which areas other than formation planned areas of the source electrodes 13, the p type contact layers 21, and the p type source layers 22 are covered are formed. Next, by means of etching or the like, the gate insulators 11 are removed to expose the second p type semiconductor layers 23 and the third n type contact layers 24 from the gate insulators 11.

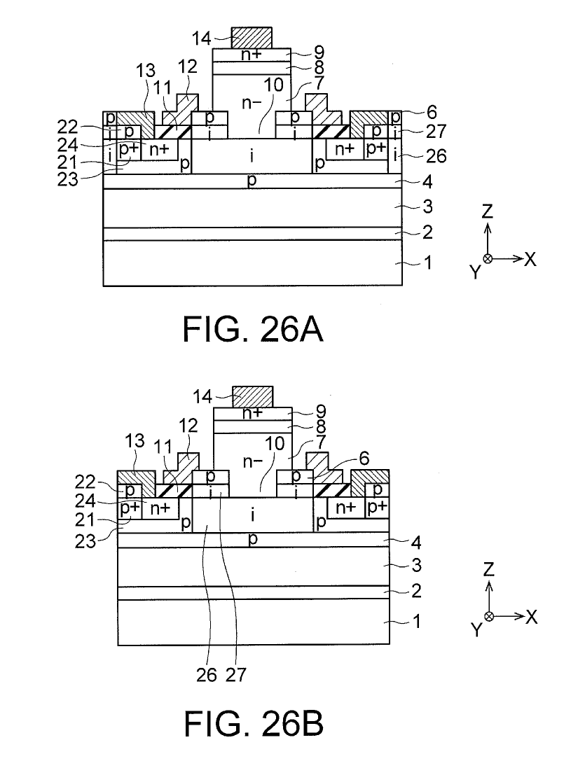

Next, as shown in FIG. 26A, using the resist masks 55, by means of RIE, the second p type semiconductor layers 23 and the third n type contact layers 24 in formation planned areas of the source electrodes 13, the p type contact layers 21, and the p type source layers 22 are removed. Next, the p type contact layers 21 and the p type source layers 22 are formed one by one on the second p type semiconductor layers 23. Next, the resist masks 55 are removed. Next, resist masks (not shown) are formed by means of lithography, and the source electrodes 13 are formed on the third n type contact layers 24 and the p type source layers 22. Next, these resist masks are removed.

Next, as shown in FIG. 26B, trenches for the element isolation are formed on the substrate 1. Consequently, the transistor is formed on the substrate 1.

Subsequently, the interlayer dielectric 15 is formed on the substrate 1. Furthermore, various interlayer dielectrics, interconnect layers, and the like are formed on the substrate 1. In such a manner, the semiconductor device of the third embodiment can be manufactured.

As describe above, the semiconductor device of the present embodiment includes the gate electrodes 12 and the source electrodes 13 in the directions of the side portions of the electron transport layer 26, the electron supply layer 27, the first p type semiconductor layer 6, or the first drift layer 7, and includes the drain electrode 14 on the first drift layer 7. Therefore, according to the present embodiment, as with the first and second embodiments, it is possible to isolate the transistor from regions containing a large number of dislocation defects, and to restrain current collapse by passing electrons through the crystals of the first drift layer 7, which consequently enables increasing the breakdown voltage of the transistor.

The substrate 1 of the first to third embodiments may be a sapphire substrate instead of a silicon substrate. In this case, after forming the transistor on the sapphire substrate, it is also possible to attach a silicon substrate to the transistor, and to isolate the transistor from the sapphire substrate by means of a laser liftoff process.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a first semiconductor layer of a first conductivity type or an intrinsic type;
a second semiconductor layer of a second conductivity type provided on the first semiconductor layer;
a third semiconductor layer of the first conductivity type or an intrinsic type provided on the second semiconductor layer;
a control electrode and a first electrode provided on a side portion of the first, second or third semiconductor layer through at least one insulating layer; and
a second electrode provided on the third semiconductor layer.

2. The device of claim 1, wherein the first electrode is electrically connected to the first semiconductor layer.

3. The device of claim 1, further comprising:
a fourth semiconductor layer of the first conductivity type electrically connected to the first electrode; and
a fifth semiconductor layer of the second conductivity type provided between the first and fourth semiconductor layers.

4. The device of claim 3, wherein the third semiconductor layer is in contact with the first and second semiconductor layers.

5. The device of claim 3, wherein the control electrode is provided on the fifth semiconductor layer through the insulating layer.

6. The device of claim 1, wherein the first semiconductor layer includes a first nitride semiconductor layer, and a second nitride semiconductor layer provided on the first nitride semiconductor layer.

7. The device of claim 6, wherein the second semiconductor layer is provided on the second nitride semiconductor layer.

8. The device of claim 6, further comprising:
a fourth semiconductor layer of the first conductivity type electrically connected to the first electrode; and
a fifth semiconductor layer of the second conductivity type provided between the first and fourth semiconductor layers,
wherein the control electrode is provided on the second semiconductor layer, and is provided on the fifth semiconductor layer through the insulating layer.

9. The device of claim 1, further comprising:
a first set of sixth and seventh semiconductor layers of the second conductivity type sequentially provided on the second semiconductor layer; and
a second set of sixth and seventh semiconductor layers of the second conductivity type sequentially provided on the second semiconductor layer,
wherein the first electrode is provided on the seventh semiconductor layers of the first and second sets, and is provided between the first set of sixth and seventh semiconductor layers and the second set of sixth and seventh semiconductor layers.

10. The device of claim 3, further comprising:
a sixth semiconductor layer of the second conductivity type in contact with the fourth and fifth semiconductor layers; and
a seventh semiconductor layer of the second conductivity type provided on the sixth semiconductor layer,
wherein the first electrode is provided on the seventh semiconductor layer.

11. The device of claim 1, wherein the first, second and third semiconductor layers are nitride semiconductor layers provided on a silicon substrate.

12. The device of claim 11, wherein the first, second and third semiconductor layers contain gallium and nitrogen.

13. A method of manufacturing a semiconductor device, comprising:
forming a first semiconductor layer of a first conductivity type or an intrinsic type;
forming a second semiconductor layer of a second conductivity type on the first semiconductor layer;
forming a third semiconductor layer of the first conductivity type or an intrinsic type on the second semiconductor layer;
forming at least one insulating layer, a control electrode and a first electrode on a side portion of the first, second or third semiconductor layer, the insulating layer interposing between the side portion of the first, second or third semiconductor layer and the control electrode, and between the side portion of the first, second or third semiconductor layer and the first electrode; and
forming a second electrode on the third semiconductor layer.

14. The method of claim 13, wherein the first electrode is electrically connected to the first semiconductor layer.

15. The method of claim 13, further comprising:
forming a fifth semiconductor layer of the second conductivity type in contact with the first semiconductor layer; and
forming a fourth semiconductor layer of the first conductivity type in contact with the fifth semiconductor layer,
wherein the first electrode is electrically connected to the fourth semiconductor layer.

16. The method of claim 15, wherein the third semiconductor layer is formed to be in contact with the first and second semiconductor layers.

17. The method of claim 13, wherein the first semiconductor layer includes a first nitride semiconductor layer, and a second nitride semiconductor layer that is formed on the first nitride semiconductor layer.

18. The method of claim 17, further comprising:
forming a fifth semiconductor layer of the second conductivity type in contact with the first semiconductor layer; and
forming a fourth semiconductor layer of the first conductivity type in contact with the fifth semiconductor layer,
wherein the control electrode is formed on the second semiconductor layer, and is formed on the fifth semiconductor layer through the insulating layer.

19. The method of claim 13, further comprising:
forming a first set of sixth and seventh semiconductor layers of the second conductivity type on the second semiconductor layer; and
forming a second set of sixth and seventh semiconductor layers of the second conductivity type on the second semiconductor layer,
wherein the first electrode is formed on the seventh semiconductor layers of the first and second sets, and is formed between the first set of sixth and seventh semiconductor layers and the second set of sixth and seventh semiconductor layers.

20. The method of claim 15, further comprising:
forming a sixth semiconductor layer of the second conductivity type in contact with the fourth and fifth semiconductor layers; and
forming a seventh semiconductor layer of the second conductivity type on the sixth semiconductor layer,
wherein the first electrode is formed on the seventh semiconductor layer.
